(19) United States
(12) Patent Application Publication
(10) Pub. No.: US 2010/0078753 A1
(43) Pub. Date: Apr. 1, 2010

(54) Flow Sensor and Method of Fabrication

(75) Inventors: Mehran Mehregany, San Diego, CA (US); Nelsimar Moura Vandelli, JR., Cleveland, OH (US)

Correspondence Address: DEMONT & BREYER, LLC, 100 COMMONS WAY, Ste. 250, HOLMDEL, NJ, 07733, US

(73) Assignee: FLOWMEMS, INC., St. Paul, MN (US)

(21) Appl. No.: 12/243,941

(22) Filed: Oct. 1, 2008

(51) Int. Cl. H01L 21/28; H01L 29/66

(52) U.S. Cl. 257/467; 438/54; 257/E21.158; 257/E29.347

(57) ABSTRACT

A method for forming a flow sensor having self-supported heat-carrying elements is disclosed. Self-supported heat-carrying elements are capable of operating with higher thermal efficiency, enabling lower power consumption and higher sensitivity, due to a lack of heat loss into a supporting membrane. Self-supported heat-carrying elements facilitate wider operating temperature range and compatibility with harsh media.

### FIELD OF THE INVENTION

The present invention relates to sensors in general, and, more particularly, to flow sensors.

### BACKGROUND OF THE INVENTION

The ability to accurately measure fluid flow, such as air flow, is becoming more important, particularly as the need for energy efficiency has become critical in many applications. Many approaches of different complexities have been used in the prior-art to form flow sensors in the prior art—from simple resistance-based sensors to fully integrated micro-electro-mechanical (MEMS) systems.

The simplest flow sensors comprise a single hot wire or thermistor that is mounted on the end of a probe, which is inserted into a flow stream. A temperature drop in response to the presence of fluid flow causes a change in the resistance of the hot wire or thermistor.

Improved flow sensors were enabled by the monolithic integration of heaters and temperature sensors on a common silicon substrate. A typical conventional flow sensor comprises a heat generating element and one or two temperature sensors arrayed in close proximity to the heat generator. In the presence of fluid flow, the heat detected by the temperature sensor(s) changes and an output signal is generated. Such flow sensors employ thin-film conductors in heaters and temperature sensors. Typically, these thin-film conductors comprise polysilicon or thin-film metals that are disposed on a dielectric layer disposed on a substrate, such as a silicon wafer. The dielectric layer electrically isolates the heat-carrying devices from the underlying substrate, while also impeding the flow of heat from the elements into the silicon material. In the absence of fluid flow, each temperature sensor receives an equal amount of heat from the heater. In the presence of fluid flow, however, the temperature sensors receive different amounts of heat from the heater. Such flow sensors are capable of sensitive detection of flow, flow rate, and flow direction based on the difference in the outputs from the temperature sensors.

MEMS technology has been exploited to yield even more advanced flow sensors that provide further improvement in signal-to-noise ratio (SNR) and increased sensitivity. Examples of such flow sensors include those disclosed in U.S. Pat. No. 4,478,076, issued Oct. 23, 1984 and U.S. Pat. No. 6,871,538, issued Mar. 29, 2005. Such flow sensors also include monolithically integrated heaters and temperature sensors; however, the dielectric layer on which the heat-carrying elements reside comprises a membrane that is suspended above the substrate. This further reduces the flow of heat from the heat-carrying elements into the silicon. Silicon nitride and silicon dioxide are materials that are often used as dielectric membrane material. In some applications, silicon dioxide is preferred due to its relatively lower thermal conductivity, while in some applications, silicon nitride is preferred due to its relatively high mechanical robustness. In some MEMS-based flow sensors, signal conditioning electronics have also been monolithically integrated to improve noise immunity.

Although the state-of-the-art in flow sensors has advanced in recent years, the sensitivity, accuracy, operating temperature range, and media compatibility of prior-art flow sensors is still deficient for many applications. As a result, a flow sensor that is characterized by one or more of: increased SNR; improved sensitivity; expanded flow rate range; less power consumption; and improved tolerance to harsh operating conditions; would represent a significant advance in the art.

### SUMMARY OF THE INVENTION

The present invention provides a flow sensor that can exhibit at least one of higher measurement sensitivity, wider operating temperature range, and improved media compatibility, as compared to the prior-art. In some embodiments, flow sensors in accordance with the present invention comprise a heater and a temperature sensor, each of which is self-supported over a cavity formed in a substrate.

The present invention is enabled by the recognition that the benefits of using single-crystal silicon as the primary structural component for heat carrying elements, such as heater elements and temperature sensing elements, outweigh the negatives a device designer would normally associate with its use in this capacity. Specifically, single-crystal silicon structures that are thick enough to be self-supporting and are characterized by a relatively low electrical resistance per unit length have a high thermal conductance. Due to these perceived limitations, a device designer would normally be drawn away from the use of self-supported silicon structures in heat carrying elements. The inventors, however, recognized that single-crystal structures of sufficient thickness would obviate the need for a membrane to support the heater and temperature sensors above a substrate, which is typically required in prior-art devices. Since embodiments of the present invention do not include such a membrane, undesired heat dissipation due to thermal conductance in the membrane is eliminated. In addition, for single-crystal structures of suitable thickness: (i) the overall thermal efficiency of such elements can be improved over comparable prior art devices; and (ii) sensor sensitivity can be increased due to the fact that heat dissipation from a heater to a temperature sensor through the membrane is eliminated.

Some embodiments of the present invention comprise one or more self-supported structures, such as a heater element and/or temperature sensor, wherein each self-supported structure comprises a portion that is disposed over a cavity formed in the substrate. The presence of the cavity mitigates or eliminates significant heat conduction from the suspended portion into the substrate material. Each self-supported structure comprises a central core of single-crystal silicon that is surrounded by a dielectric material, an arrangement that mitigates or eliminates deformation of device elements over the sensor operating temperature range due to bi-material effects, a common problem in prior art. In some embodiments, the dielectric material:
i. protects the single-crystal silicon from etch chemicals used to form a cavity in the substrate; or
ii. enhances the mechanical strength of the self-supported device elements; or
iii. provides isolation of the device elements from media during flow sensing operation; or
iv. any combination of i, ii, and iii.

Some embodiments of the present invention comprise a silicon-on-insulator substrate having one or more through-substrate contacts. These through-substrate contacts enable electrical connectivity between backside contacts and thermal device elements formed in the active layer of the silicon-on-insulator substrate. In some embodiments, through-substrate contacts enable the elimination of metal wire bond pads and wire bonds from the front-side surface. As a result, damage to exposed wire bonds by media flow is eliminated. Further, media compatibility is enhanced and overall sensor size can be reduced.

Some embodiments of the present invention comprise temperature sensors that are positioned at a plurality of distances from a heater element. Such a configuration affords an ability to sense fluid flow across the flow sensor at a plurality of flow ranges within a small overall sensor size.

Some embodiments of the present invention comprise temperature sensors that include a plurality of temperature sensing elements, wherein these temperature sensing element are positioned at a plurality of distances from a heater element. Such temperature sensors are capable of sensing fluid flow across a wide flow rate range.

Some embodiments of the present invention comprise a heater element that has a sculpted shape. In some embodiments, the heater element is sculpted to create a cross-sectional resistance profile along an axis of the heater element. In some embodiments, the heater element is sculpted to counteract the effects of heat loss into the substrate at the anchor points of the heater element. As a result, some of these embodiments comprise a heater element that emits a substantially uniform level of heat along this axis.

An embodiment of the present invention comprises: a method for forming a flow sensor, wherein the method comprises: forming a cavity in a first region of a bulk layer; forming a heater element having a first portion disposed above the first region, wherein the heater element comprises an inner core of substantially single-crystal silicon and an outer shell comprising a first dielectric; and forming a first temperature sensor having a second portion disposed above the first region, wherein the first temperature sensor comprises an inner core of single-crystal silicon and an outer shell comprising the first dielectric; wherein the first portion and the second portion are physically decoupled from one another in the first region.

### BRIEF DESCRIPTION OF THE DRAWINGS

FIG. 1 depicts a portion of a flow sensor in accordance with the prior-art.

FIGS. 2A and 2B depicts a cross-sectional view of details of a flow sensor in accordance with an illustrative embodiment of the present invention.

FIG. 2B depicts a top view of details of a flow sensor in accordance with an illustrative embodiment of the present invention.

FIG. 3 depicts a method suitable for forming a flow sensor in accordance with the illustrative embodiment of the present invention.

FIGS. 4A-4E depict cross-sectional diagrams of details a flow sensor, at different stages of fabrication, in accordance with the illustrative embodiment of the present invention.

FIGS. 5A-5E depict top views of details of a flow sensor, at different stages of fabrication, in accordance with the illustrative embodiment of the present invention.

FIG. 6A depicts a top view of details of a temperature sensor in accordance with a first alternative embodiment of the present invention.

FIG. 6B depicts a top view of details of a temperature sensor in accordance with a second alternative embodiment of the present invention.

FIG. 6C depicts a top view of details of a temperature sensor in accordance with a third alternative embodiment of the present invention.

FIG. 7 depicts a cross-sectional diagram of a temperature sensor in accordance with a fourth alternative embodiment of the present invention.

FIG. 8 depicts a method suitable for forming a temperature sensor in accordance with the fourth alternative embodiment of the present invention.

FIG. 9 depicts a top view of details of a flow sensor in accordance with a fifth alternative embodiment of the present invention.

FIG. 10 depicts a top view of details of a flow sensor in accordance with a sixth alternative embodiment of the present invention.

FIG. 11 depicts a top view of details of a flow sensor in accordance with a seventh alternative embodiment of the present invention.

### DETAILED DESCRIPTION

The following terms are defined for use in this Specification, including the appended claims:
Single-crystal material means material having a crystalline structure that comprises substantially only one type of unit-cell. A single-crystal layer, however, may exhibit some crystalline defects such as stacking faults, dislocations, or other commonly occurring crystalline defects. Examples of single-crystal materials include, without limitation, single-crystal silicon, single-crystal germanium, single-crystal III-V semiconductors and their compounds, and single-crystal silicon carbide.

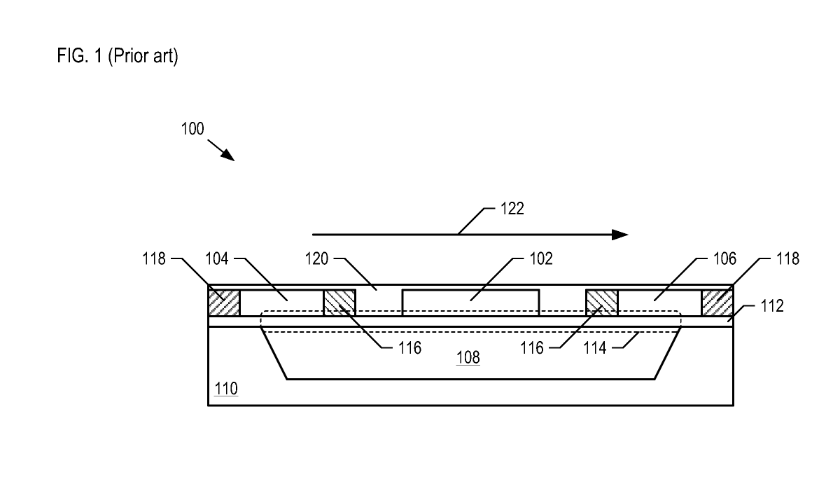

FIG. 1 depicts a cross-sectional view of a schematic diagram of a portion of a flow sensor in accordance with the prior-art. Flow sensor 100 comprises heater 102, temperature sensors 104 and 106, membrane 114, and substrate 110. Exemplary prior-art flow sensors are disclosed in U.S. Pat. No. 4,478,076, issued Oct. 23, 1984 and U.S. Pat. No. 6,871,538, issued Mar. 29, 2005.

Heater 102 is a thin-film heater. Heater 102 is typically made of conductive polysilicon or a thin-film metal. Heater 102 has a shape suitable for its designed resistance value and heat profile for operation as a resistive heater element.

Temperature sensors 104 and 106 are thermopiles, each comprising a plurality of hot and cold junctions that are connected in series. Each of temperature sensors 104 and 106 provides a voltage output that is representative of the temperature differential between its hot junctions 116 and cold junctions 118. The amount of heat these hot junctions receive is based upon the flow of air along sense direction 122. For example, in the presence of air flow along flow direction 122, temperature sensor 106 will receive more heat from heater 102 than is received by temperature sensor 104. As a result, a temperature differential representative of the magnitude of the air flow is sensed by temperature sensors 104 and 106. Materials typically used to form such thermopiles include conventional thermocouple materials, such as polysilicon, aluminum, vanadium, tungsten, cobalt, and the like.

Substrate 110 is a silicon substrate suitable for providing a stable platform on which heater 102 and temperature sensors 104 and 106 are formed.

Dielectric layer 112 is a thin film of dielectric disposed on substrate 110. Typically, dielectric layer 112 is a layer of silicon dioxide, silicon nitride, or a combination of the two. In order to reduce the flow of heat from the heater 102 and hot junctions 116 into the substrate, a portion of substrate 110 is removed to form cavity 108. By virtue of cavity 108, a portion of dielectric layer 112 forms suspended membrane 114.

Hot and cold junctions 116 and 118, respectively, are junctions of dissimilar materials that generate a voltage as a function of their temperature by virtue of the thermoelectric (a.k.a., “Seebeck”) effect. The magnitude of the generated voltage is based upon a Seebeck coefficient associated with the specific types of materials used for the junction (i.e., their “Seebeck coefficient”).

Hot junctions 116 are located on suspended membrane 114, which reduces the flow of heat from the temperature sensors into substrate 110. Hot junctions 118 are in close proximity to heater 102; therefore, their temperature is strongly affected by the amount of heat they receive from heater 102.

Cold junctions 118, on the other hand, are located off suspended membrane 114 and are, therefore, in closer proximity to substrate 110. As a result, the substrate acts as a heat sink that keeps the temperature of cold junctions 118 relatively stable and substantially equivalent to the ambient temperature of flow sensor 100. Cold junctions 118, therefore, act as a reference for hot junctions 116.

Dielectric layer 120 is a layer of silicon nitride and/or silicon dioxide that encapsulates the heater and temperature sensors.

In the prior art, it is necessary to include a membrane that supports the heater and temperature sensors (i.e., membrane 114) because the mechanical characteristics of the materials used to form the heaters and temperature sensors. As is discussed below, these elements typically comprise either polysilicon or thin-film metals or a combination. Such materials exhibit inherent material properties such as residual stresses that typically preclude them from acting as free-standing elements. Additionally, and especially when they are used in combination, when these materials are exposed to high temperatures or large temperature swings (such as those commonly occur in many sensor applications), bi-material effects can substantially degrade the performance of such sensors. Bi-material effects, such as bending, deformation, twisting, and the like, arise due to a mismatch of thermal expansion coefficients of dissimilar materials. As a result, induced bi-material effects can limit the operating range of prior-art sensors since they are proportional to the temperature excursion to which the sensors are subjected. The inclusion of a dielectric membrane provides a means for reducing, somewhat, the deformation of the heating and temperature sensing elements by virtue of its mechanical stiffness.

In order to reduce its effect on the measurement sensitivity of flow sensor 100, the material used for dielectric layer 112 (and, therefore, membrane 114) is typically selected for its high thermal resistivity as well as its mechanical properties. High thermal resistivity is important because membrane 114 provides a direct thermal path between the heater and heat elements and the substrate. Any heat flow between these elements through membrane 114 reduces the sensitivity of the flow sensor to the flow of fluid across it. In fact, the thermal characteristics of these membranes has been a focus of much of the prior art. Significant concern over the thermal conductivity of the membrane material is evinced, for example, in U.S. Pat. No. 4,478,076, which discloses that “ . . . the supporting silicon nitride film has such a low thermal conductivity that sensing resistor grids 22 and 24 can be located immediately adjacent to heating resistor grid 26 and yet can allow most of the heat conducted to sensing resistor 22 and 24 from heater resistor 26 to pass through the surrounding air rather than through the supporting nitride film.” See, e.g., Col. 4, lines 8-14.

Materials Considerations

The most common material used as heating and temperature sensing elements in early flow sensors of this type were thin-film metals. Unfortunately, thin-film metals are known to have several disadvantages for such applications. First, the mechanical and electrical properties of metals can change due to creep, grain growth, self-annealing effects, etc., some or all of which are accelerated when subjected to elevated temperatures. Second, the melting point for most thin-film metals can limit the operating range of such flow sensors. Third, thin-film metals typically exhibit inherent residual stress that can lead to physical deformation upon release from the underlying substrate. Such physical deformation may be further exacerbated at higher temperatures. Finally, when thin-film metals are in contact with other materials, they can exhibit significant bi-material effects, such as bending, twisting, or other deformation, due to a mismatch in thermal expansion coefficients (TECs) of the materials. Each of these issues can have a deleterious effect on the performance of a flow sensors based on thin-film metal elements. In the prior art, some of these deleterious effects have been mitigated through the inclusion of a membrane to support the thin-film metal structures.

In response to the problems associated with thin-film metals, polysilicon heater elements and temperature sensor elements were developed. Unfortunately, there are a number of disadvantages associated with polysilicon as well. First, it is well-known that the mechanical properties of polysilicon can vary significantly from deposition system to deposition system, as well as from deposition to deposition within the same system. Second, it is virtually impossible to reliably deposit a polysilicon layer that is characterized by very low residual stress and/or a lack of a stress gradient through its thickness. Third, the deposition of polysilicon typically requires a long deposition time, which increases production costs and ties up fabrication equipment. For polysilicon films of sufficient thickness to potentially enable self-supporting structures (i.e., thicker than approximately 1-2 microns), the length of deposition time required is particularly undesirable. Fourth, deposition of a thick polysilicon film necessitates significant maintenance of the deposition equipment after such films are deposited. Finally, when used in an application wherein it is exposed to high heat (e.g., as a heater element), polysilicon can exhibit self-annealing effects that can dramatically affect its mechanical properties. As with thin-film metals, each of these issues can have a deleterious effect on the performance of a flow sensors based on thin-film metal elements. Although some performance improvements were demonstrated with the replacement of thin-film metals by polysilicon, the use of polysilicon does not obviate the need for the inclusion of a membrane to support the heater and temperature sensor elements.

It is an aspect of the present invention that the inventors recognized that single-crystal materials used as a structural material in heater and temperature sensor elements affords significant advantages over both polycrystalline materials and thin-film metals for applications such as flow sensors. Advantages of single-crystal materials, such as single-crystal silicon, as a structural material have been recognized by designers in other technology areas such as optical switching and inertial navigation systems. In such applications, however, the single-crystal silicon was exploited primarily, if not exclusively, for its structural characteristics. When used in thermal device elements, such as heaters or temperature sensing elements, however, a designer would be drawn away from the use of single-crystal silicon due to its relatively low electrical resistivity and high thermal conductivity.

For example, in the case of a heater or temperature sensing element, single-crystal silicon might be considered particularly unattractive because it is difficult to obtain single-crystal silicon films thin enough to achieve a sufficiently small cross-sectional area. A small cross-sectional area is desirable to optimize the combination of electrical resistance and thermal efficiency requirements. In contrast, polysilicon and thin-film metals are more naturally suited to the formation of extremely thin (and, therefore, thermally efficient) elements. Such materials are characterized by sufficiently high electrical conductivity to keep resulting resistance values within desirable ranges (e.g., a few hundred Ohms for heaters and a few kilo Ohms to tens-of-kilo Ohms for temperature sensors). A designer, therefore, would be drawn toward the use of polysilicon or thin-film metals and drawn away from the use of single-crystal silicon as a heater element.

The present inventors recognized, however that because single-crystal material structures can be self-supporting, heat conduction between thermal device elements through a supporting membrane can be eliminated. As a result, the design space for these elements is expanded to allow optimization of electrical and thermal requirements. This, in turn, enables improved performance of such single-crystal material-based sensors as compared with the performance of sensors based on polysilicon- or metal-based heater and temperature sensor elements. Based upon this recognition, therefore, the use of a single-crystal material as a fundamental structural component of suspended thermal device elements is a principle aspect of the present invention.

The self-supporting capacity of the heater and temperature sensor elements arises primarily from the fact that single-crystal materials typically exhibit little or no residual stress and little or no stress gradient through its thickness. As a result, such elements exhibit little or no deformation when released from the underlying layers.

Further, the fact that single-crystal materials lack significant material stress enables creative sculpting of the temperature sensor and heater regions without the risk of stress-induced deformation of the elements. Specifically, the use of a single-crystal material enables, among other things:
i. enhanced sensitivity for a temperature sensor; or
ii. enhanced thermal performance and reliability of a heater element; or
iii. a temperature sensing element that exhibits tailored temperature gradients along its length; or
iv. a temperature sensing element that exhibits uniform temperature gradients along its length; or
v. a temperature sensor that is operable over an expanded flow rate range; or
vi. any combination of i, ii, iii, iv, and v.

Still further, high aspect ratio structures (i.e., thick, narrow structures) can be readily formed using low-stress single-crystal silicon as the dominant structural material in thermal elements.

It was further recognized by the inventors that the use of single-crystal silicon as the mechanical material can provide additional advantages. For example, the use of single-crystal silicon enables formation of thermal sensors that exhibit a higher Seebeck coefficient than can be achieved with either polysilicon or thin-metal films. As a result, temperature sensors having higher sensitivity can be formed in single-crystal silicon.

Further, single-crystal silicon is more amenable to the use of ion implantation for doping the silicon. As a result, temperature sensors comprising a very large number of narrow-width p-n junctions can be easily fabricated.

Finally, silicon-on-insulator wafers are readily available at reasonable cost. In many cases, this results in a lower overall cost when compared to the cost associated with depositing a low-stress thin-film of metal or polysilicon or dielectric layer that serves as membrane. As a result, the process complexity and fabrication cost associated with producing flow sensor wafers can be reduced by the use of single-crystal silicon heater and temperature sensor elements.

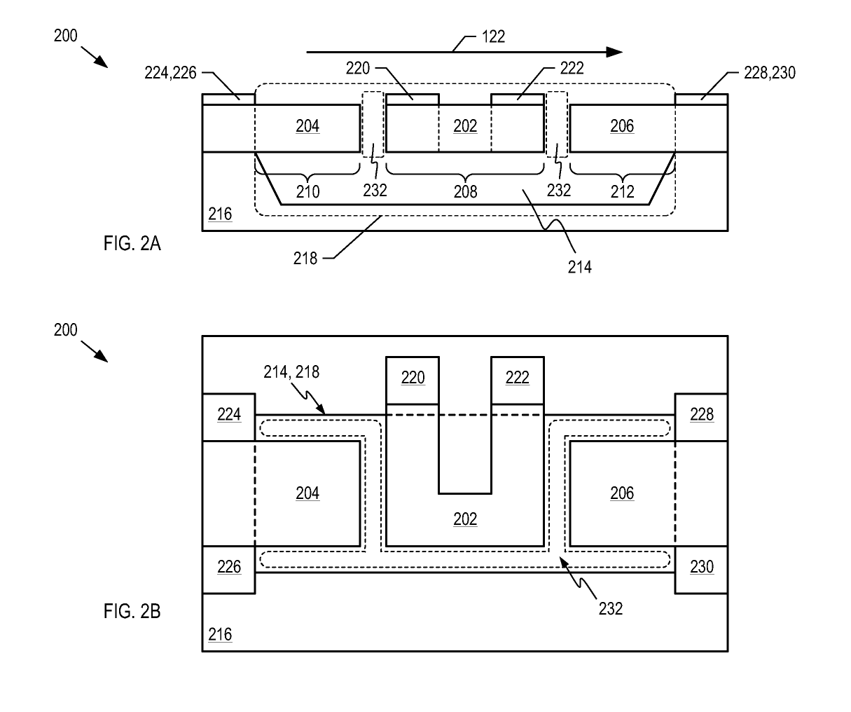

FIGS. 2A and 2B depict a cross-sectional view and top view, respectively, of details of a flow sensor in accordance with an illustrative embodiment of the present invention. Flow sensor 200 comprises heater 202, temperature sensors 204 and 206, and substrate 216.

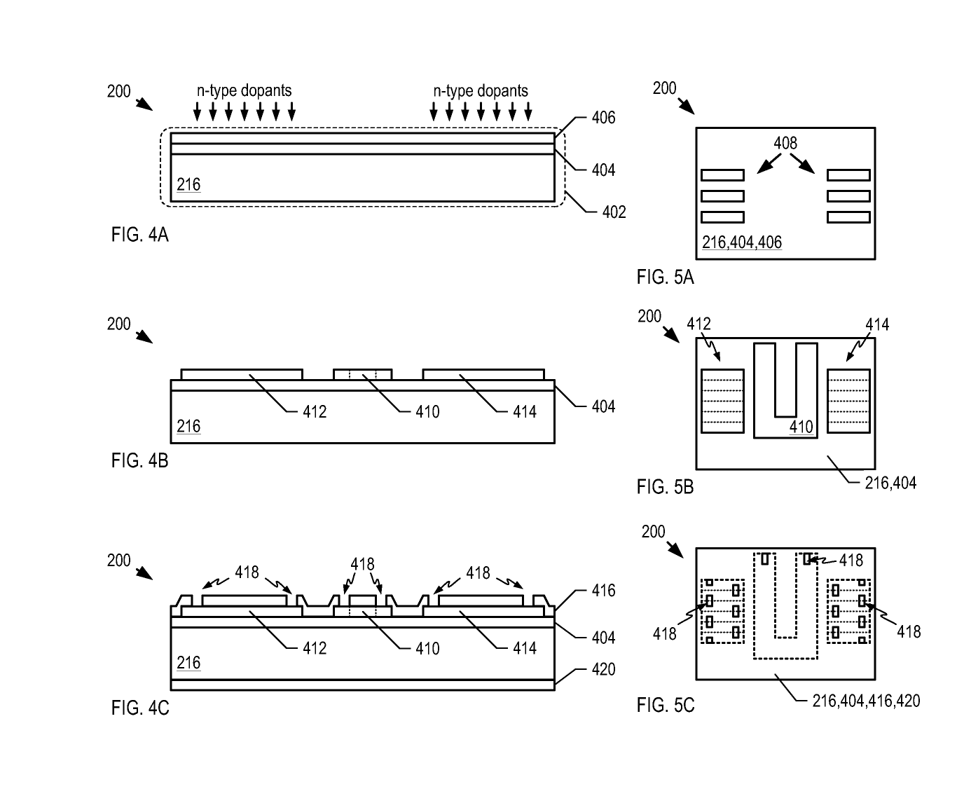

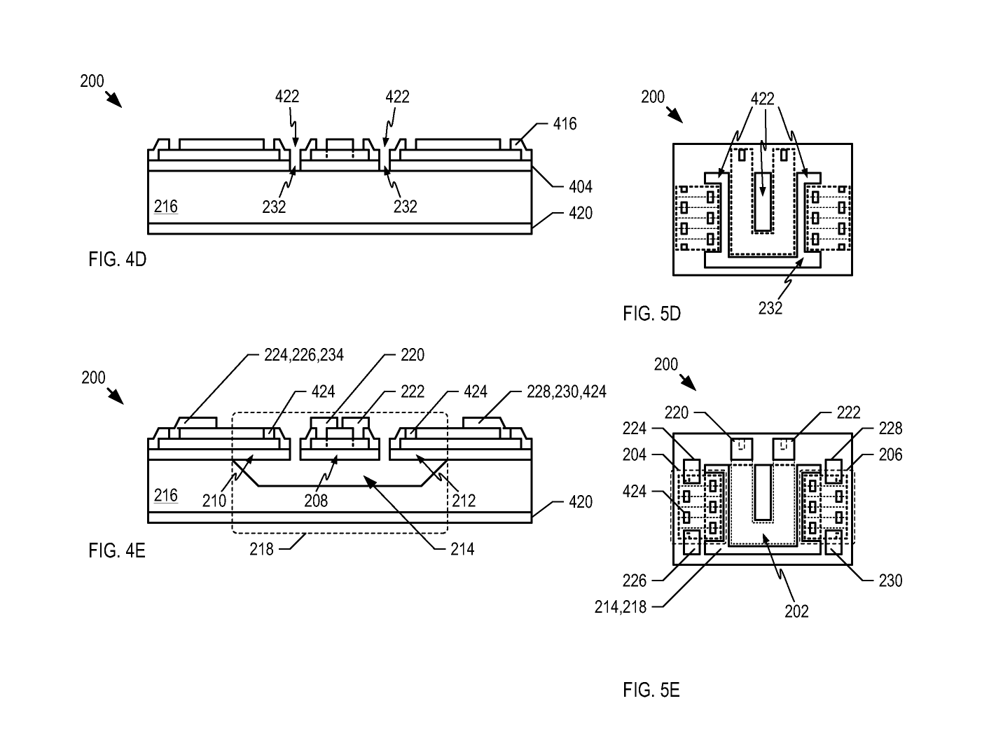

Heater 202 is a resistive heater element comprising a core of single-crystal silicon and an outer shell of silicon dioxide. Heater 202 generates heat in response to a current that flows between contacts 220 and 222. Portion 208 of heater 202 is disposed above cavity 214, the outer perimeter of which defines region 218. As a consequence, heat flow from the portion 208 into substrate 216 is substantially limited to that portion of heater 202 that is in direct physical contact with the substrate (i.e., that portion that is outside region 218). Although in the illustrative embodiment heater 202 is characterized by a u-shape, it will be clear to one skilled in the art, after reading this embodiment, that heater 202 can be formed in any of a wide variety of shapes. Heater 202 is described in more detail below and with respect to FIGS. 4A-E and 5A-E.

Temperature sensor 204 is a thermopile comprising a core of single-crystal silicon and an outer shell of silicon dioxide. Portion 210 of temperature sensor 204 is disposed above cavity 214. As a consequence, heat flow from the portion 210 into substrate 216 is substantially limited to that portion of heater 202 that is in direct physical contact with the substrate. The core of single-crystal silicon comprises a plurality of p-n junctions that form a plurality of hot junctions, located within region 218, and a plurality of cold junctions, located outside region 218.

Temperature sensor 206 is a thermopile comprising a core of single-crystal silicon and an outer shell of silicon dioxide. Portion 212 of temperature sensor 206 is disposed above cavity 214. As a consequence, heat flow from the portion 212 into substrate 216 is substantially limited to that portion of heater 206 that is in direct physical contact with the substrate. The core of single-crystal silicon comprises a plurality of p-n junctions that form a plurality of hot junctions, located within region 218, and a plurality of cold junctions, located outside region 218. Temperature sensors 204 and 206 are described in more detail below and with respect to FIGS. 4A-E and 5A-E. It will be clear to one skilled in the art that temperature sensors 204 and 206 can comprise any element suitable for providing an electrical signal that is based upon temperature or heat flux. Suitable devices for use in one or both of temperature sensors 204 and 206 include, without limitation, p-n junctions, thermocouples, thermistors, thermopiles, piezoelectric materials, pyroelectric materials, bolometers, metal-semiconductor junctions, bipolar transistors, field effect transistors, bimetallic strips, and the like. It will also be clear that temperature sensors 204 and 206 may have any suitable shape, subject to practical fabrication considerations.

Portions 208, 210, and 212 are physically decoupled within region 218 by virtue of the removal of material from region 232, as will be described below.

Although the illustrative embodiment depicts a flow sensor capable of monitoring fluid flow along a single axis, by virtue of its single pair of temperature sensors arrayed along a single axis, it will be clear to one skilled in the art, after reading this specification, how to make and use alternative embodiments of the present invention that comprise any number of temperature sensors arranged in any fashion about one or more heaters. As a result, in some embodiments of the present invention flow and flow rate can be measured along more than one axis.

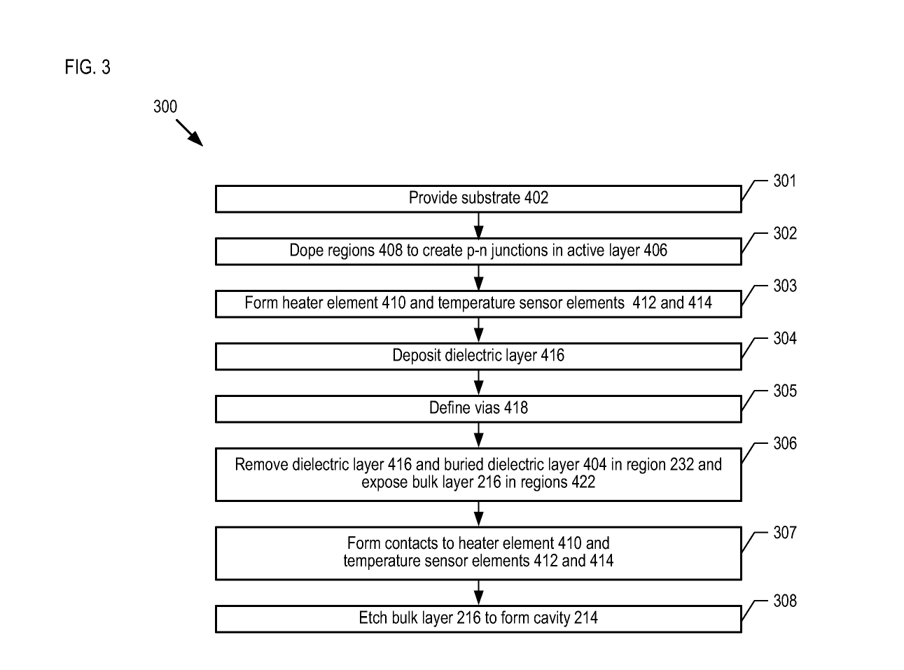

FIG. 3 depicts a method suitable for forming a flow sensor in accordance with the illustrative embodiment of the present invention.

FIGS. 4A-4E depict cross-sectional diagrams of details a flow sensor, at different stages of fabrication, in accordance with the illustrative embodiment of the present invention.

FIGS. 5A-5E depict top views of details of a flow sensor, at different stages of fabrication, in accordance with the illustrative embodiment of the present invention. In order to more facilitate a clear illustration of the present invention, fabrication of a flow sensor in accordance with the illustrative embodiment of the present invention will be described with continuing reference to FIGS. 3, 4A-E, and 5A-E.

Referring now to FIGS. 4A and 5A, method 300 begins with operation 301, wherein substrate 402 is provided. Substrate 402 is a silicon-on-insulator substrate that comprises bulk layer 216, buried dielectric layer 404, and active layer 406.

Bulk layer 216 is a conventional single-crystal silicon handle wafer that provides structural support for flow sensor 200. Bulk layer 216 has a background doping level sufficient to make it suitably electrically conductive. Typical silicon handle wafers have a thickness in the range of approximately 100 microns to approximately 2000 microns, although it will be clear to one skilled in the art that bulk layer 216 need not be limited to this range of thicknesses. In some embodiments, handle bulk layer 216 is a layer of single-crystal semiconductor material that is disposed on a conventional handle wafer. In some embodiments, bulk layer 216 is a material other than silicon. Suitable materials for use in bulk layer 216 include, without limitation, compound semiconductors, germanium, dielectrics, ceramics, metals, organic materials, and organic material composites.

Buried dielectric layer 404 is a layer of silicon dioxide having a thickness of approximately 0.3 microns. In some embodiments, buried dielectric layer 404 has a thickness within the range of approximately 0.1 micron to approximately 5 microns, although it will be clear to one skilled in the art that buried dielectric layer 404 need not be limited to this range of thicknesses. In some embodiments, buried dielectric layer comprises materials other than silicon dioxide, such as other glasses, silicon nitride, silicon oxynitride, and the like. Buried dielectric layer 404 provides electrical isolation between bulk layer 216 and active layer 406. In some embodiments, buried dielectric layer 404 also acts as an etch stop during the patterning of active layer 406.

Active layer 406 is a layer of p-type single-crystal silicon having a thickness of approximately 2 microns. In some embodiments, active layer 406 is a layer of n-type single-crystal silicon. In some embodiments, active layer 406 has a thickness within the range of approximately 0.1 micron to approximately 5 microns, although it will be clear to one skilled in the art that active layer 406 need not be limited to this range of thicknesses. The thickness of active layer 406 is selected to enable a portion 208 of heater 202 and portions 210 and 212 of temperature sensors 204 and 206, respectively, to be self-supported after formation of cavity 214 without significant deformation from their unreleased state. An additional consideration for the selection of the thickness of active layer 406 is optimized thermal efficiency and electrical characteristics of the heater element 410 and temperature sensor elements 412 and 414. These considerations result in a design trade-off, which might dictate that the thickness of active layer 406 is different for effective use in different applications. As the thickness of active layer 406 is increased, however, mechanical rigidity of the device element can increase, resistance of resistive device elements can decrease, packing density of ion-implanted thermopile thermocouples can decrease, and the thermal efficiency of thermal elements can decrease. Although the illustrative embodiment comprises an active layer comprising single-crystal silicon, it will be clear to one skilled in the art, after reading this specification, how to specify, make, and use alternative embodiments of the present invention wherein active layer 406 comprises a different material that has a substantially single-crystal crystal structure. Suitable materials for use in active layer 406 include, without limitation, compound semiconductors, germanium, ceramics, silicon carbide, germanium, metals, organic materials, and organic material composites.

At operation 302, regions 408 are formed in active layer 406. Regions 408 are doped with an n-type dopant using ion implantation to create a substantially uniform doping profile through the thickness of active layer 406. Regions 408 are referred to as counter-doped regions because they are doped with the opposite dopant type from that of active layer 406. Regions 408 are distributed into two columns of three n-type regions each, which are interposed by regions of p-type active layer 406. Each column, therefore, forms a plurality of p-n junctions, which act as the bases for a plurality of thermocouples as will be described below and with respect to FIGS. 4E and 5E. Although the illustrative embodiment comprises temperature sensors based on thermopiles having three n-type regions to form p-n junctions, it will be clear to one skilled in the art, after reading this specification, how to specify, make, and use alternative embodiments of the present invention wherein temperature sensors are based on thermopiles having any number of p-n junctions. The number of p-n junctions included in a thermopile is limited only by the minimum width of the n- and p-type doped regions achievable and the available real estate that can be allocated to the thermopile region.

In some embodiments, a plurality of ion implantation processes is used to implant dopant atoms at different depths within regions 408. In some embodiments, ion implantation is followed by a high-temperature anneal to redistribute and/or activate the dopant atoms. In some embodiments, regions 408 are formed through a doping method other than ion implantation, such as dopant diffusion. In some embodiments, active layer 406 is doped with an n-type dopant and regions 408 are doped with a p-type dopant. In some embodiments, regions 408 are doped only through a portion of the thickness of active layer 406.

Turning now to FIGS. 4B and 5B, at operation 303, active layer 406 is patterned using conventional photolithography and reactive ion etching to form heater element 410 and temperature sensor cores 412 and 414. Temperature sensor cores 412 and 414 comprise n-type regions 408 and their respective interleaved p-type strips of active layer 406. It should be noted that the specific shape of heater element 410 and temperature sensor cores 412 and 414 is a design consideration and that one skilled in the art may choose to form these elements in any suitable shape, subject to fabrication constraints. In some embodiments, other passive or active device elements, such as thermistors, transistors, diodes, capacitors, and the like, are formed in and/or on active layer 406 either before or after operation 303. In such embodiments the regions of active layer 406 that include such devices would also remain after the operation 303.

As depicted in FIGS. 4C and 5C, at operation 304, dielectric layers 416 and 420 are formed. Each of dielectric layers 416 and 420 is a layer of thermally grown silicon dioxide having a thickness that is substantially equal to the thickness of buried dielectric layer 404. By virtue of the fact that layer 416 (on top of heater element 410 and temperature sensor cores 412 and 414) and buried dielectric layer 404 (below heater element 410 and temperature sensor cores 412 and 414) have substantially the same thickness, the present invention mitigates or eliminates the deleterious effects caused by bi-material effects in the prior-art. As a result, embodiments of the present invention are capable of operation over a larger range of temperatures than prior-art flow sensors.

Together with buried dielectric layer 404, dielectric layer 416 encapsulates heater element 410 and temperature sensor cores 412 and 414. In some cases, the thickness of the encapsulating materials serves to increase the strength of portions 208, 210, and 212 after their release from the substrate and/or provides isolation of these device elements from media during flow sensing operation. In some embodiments, at least one of dielectric layers 416 and 420 comprises a plurality of layers of different dielectric materials.

Dielectric layer 420 serves to protect the backside and sidewalls (not shown for clarity) of bulk layer 216 during subsequent formation of cavity 218. In some embodiments wherein bulk layer 216 is a layer of material disposed on a handle wafer, layer 420 is not necessary.

In some embodiments, dielectric layers 416 and 420 are deposited layers rather than thermally grown layers. In some embodiments, dielectric layers 416 and 420 are deposited as conformal layers (i.e., layers that have substantially uniform thickness on all exposed surfaces). It is desirable that these layers have low thermal conductivity in order to provide thermal isolation between thermal elements and bulk layer 216. Materials suitable for use in dielectric layers 416 and/or 420 include, without limitation, silicon dioxide, tetraethylorthosilicate (TEOS), silicon nitride, low-stress silicon nitride, silicon oxynitride, and glasses such as spin-on glass, borosilicate glass, borophosphosilicate glass, and phosphosilicate glass.

At operation 305, vias 418 are opened through dielectric layer 416 to expose contact regions on heater element 410 and temperature sensor cores 412 and 414. In some embodiments, vias 418 are formed using conventional photolithography and reactive ion etching or lift-off. In some embodiments, a selective etch is used to etch dielectric layer 416 but stop at active layer 406.

In some embodiments, an etching technique other than conventional reactive ion etching is used to form features in active layer 406 and/or dielectric layer 416. Suitable etching techniques include, without limitation, deep reactive ion etching, ion milling, wet chemical etching, laser-assisted etching, and sand blasting. It will be clear to one skilled in the art, after reading this specification, how to form heater element 410, temperature sensor cores 412 and 414, and vias 418.

Turning now to FIGS. 4D and 5D, at operation 306, heater element 202, temperature sensor 204, and temperature sensor 206 are physically decoupled from one another within region 218. These elements are physically decoupled from one another by virtue of the removal of dielectric layer 416 and buried dielectric layer 404 in region 232. This material is removed using conventional photolithography and reactive ion etching and/or wet etching. In addition to forming region 232, regions 422, which include region 232, are formed during operation 306. The formation of regions 422 exposes bulk layer 216 in preparation for the subsequent formation of cavity 214.

It should be noted that, in some embodiments, operations 305 and 306 can be accomplished in one operation. Such a combination of operations is particularly facilitated by the use of an etchant that etches dielectric layer 416 and buried dielectric layer 404 selectively over active layer 406 and bulk layer 216.

Turning now to FIGS. 4E and 5E, at operation 307, contacts 220, 222, 224, 226, 228, 230, and interconnects 424 are formed. These contacts enable electrical connection to heater element 410 and temperature sensor cores 412 and 414. In some embodiments, these contacts and interconnects are formed using photolithography and lift-off metallization. In some embodiments, these contacts are formed using subtractive patterning techniques. At each via 418 in temperature sensor cores 412 and 414, the deposition of contact or interconnect material forms a thermocouple junction with the semiconductor material below it. For each interconnect, since one end forms a thermocouple with p-type material and the other end forms a thermocouple with n-type material, the developed voltage across the interconnect is approximately twice that of each of the individual thermocouples of which it is a part. For each of temperature sensors 204 and 206, the thermocouples formed by each interconnect 424 and those formed by their respective contacts (i.e., contacts 224 and 226 of temperature sensor 204) are electrically connected in series to form a thermopile that produces a macroscopically detectable voltage in the presence of a temperature differential.

Contacts 220, 222, 224, 226, 228, 230, and interconnects 424 comprise materials that are substantially unaffected by the etchant used to form cavity 214. Although suitable materials for use in contacts 220, 222, 224, 226, 228, 230, and interconnects 424 are determined by the type of etch used to form cavity 214, in some embodiments these materials include, without limitation, gold, tungsten, titanium-tungsten, nickel, platinum, palladium, silicides, polycrystalline semiconductors (e.g., polysilicon, polysilicon carbide, germanium, and the like. In embodiments wherein a polycrystalline semiconductor is used in this fashion, it is necessary to ensure that the semiconductor forms an Ohmic contact to underlying material that includes semiconductor material of the opposite doping type. This can be accomplished by doping the polycrystalline semiconductor contact/interconnect material to a suitable level. It will be clear to one skilled in the art, after reading this specification, how to form contacts 220, 222, 224, 226, 228, 230, and interconnects 424. In some embodiments, contacts 220, 222, 224, 226, 228, 230, and interconnects 424 comprise materials that are affected by the etchant used to form cavity 214. In such embodiments, a protective layer is disposed on contacts 220, 222, 224, 226, 228, 230, prior to the cavity etch operation. Although suitable materials for this protective layer are determined by the type of etch used to form cavity 214, in some embodiments these materials include, without limitation, silicon dioxides, silicon nitrides, silicon oxynitrides, glasses, and the like.

At operation 308, cavity 214 is formed using a crystallographic-dependent etch that etches bulk layer 216 selectively over dielectric layers 404, 416, and 420. In some embodiments, cavity 214 is formed by etching bulk layer 216 is a non-crystallographic-dependent etch. In some embodiments, cavity 214 is formed by etching bulk layer 216 in a crystallographic dependent etch, wherein regions 422 are misaligned with the crystalline orientation of bulk layer 216 to facilitate the undercutting of heater element 410 and temperature sensor cores 412 and 414 during the formation of cavity 214. It will be recognized by one skilled in the art that the shape of regions 422 are dependent upon the type of etchant used to form cavity 214, as well as the crystalline orientation (e.g., <100>, <110>, <111>, etc.) of bulk layer 216.

In some embodiments, cavity 214 is formed by patterning an opening in dielectric layer 420 to expose bulk layer 216 to an etchant. In such embodiments, the depth of cavity 214 is substantially equal to the thickness of bulk layer 216.

The formation of cavity 214 creates a significant gap between portions 208, 210, and 212 and bulk layer 216. As a result, the thermal isolation between these portions and the underlying bulk layer is improved. In addition, the presence of a significant gap between the heater and temperature sensors and the substrate enables fluid (e.g., air) to flow underneath these elements, further improving heat transfer and therefore flow sensor performance. In some prior-art flow sensors the gap between a supporting membrane and its underlying substrate is small (e.g., two microns or less). As a result, the fluid between the membrane and substrate becomes trapped as a stagnant layer. A fluid flow only exists above the heater and temperature sensors; therefore, heat is only conveyed by the fluid flow in this region, which reduces the sensitivity of the device.

Temperature sensors 204 and 206 are thermopile-based temperature sensors, which are collectively defined by the p-n junctions formed as a consequence of the formation of doped regions 408. By virtue of cavity 214, the p-n junctions located in portions 210 and 212 are substantially thermally isolated from bulk layer 216; therefore, these p-n junctions act as hot junctions in the thermopiles. The p-n junctions located outside region 218 are in thermal contact with bulk layer 216 (through buried dielectric layer 404); therefore, these p-n junctions substantially remain at the ambient temperature of flow sensor 200 and act as cold junctions in the thermopiles. By virtue of conductive bridges 424, the thermopiles comprise a plurality of thermocouples electrically connected in series.

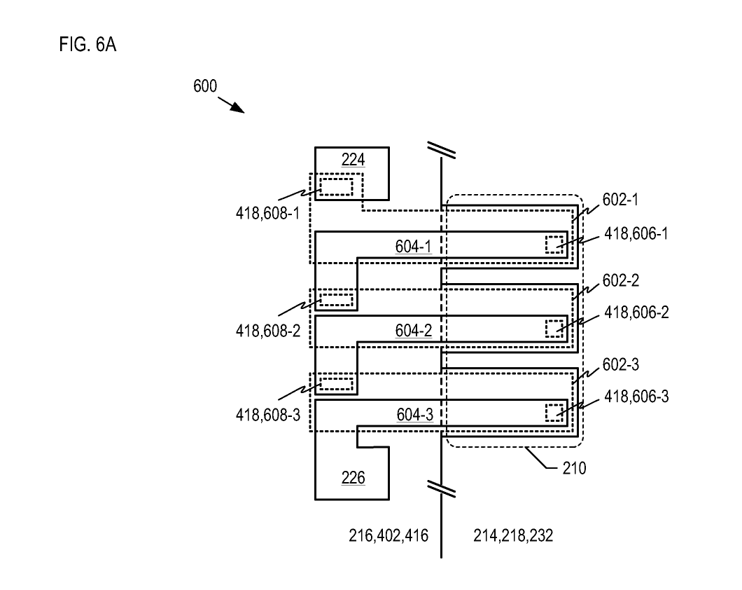

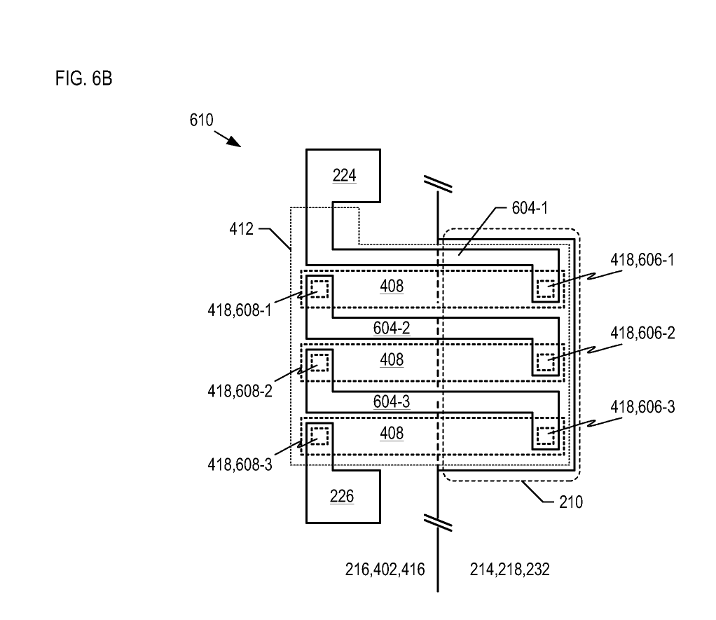

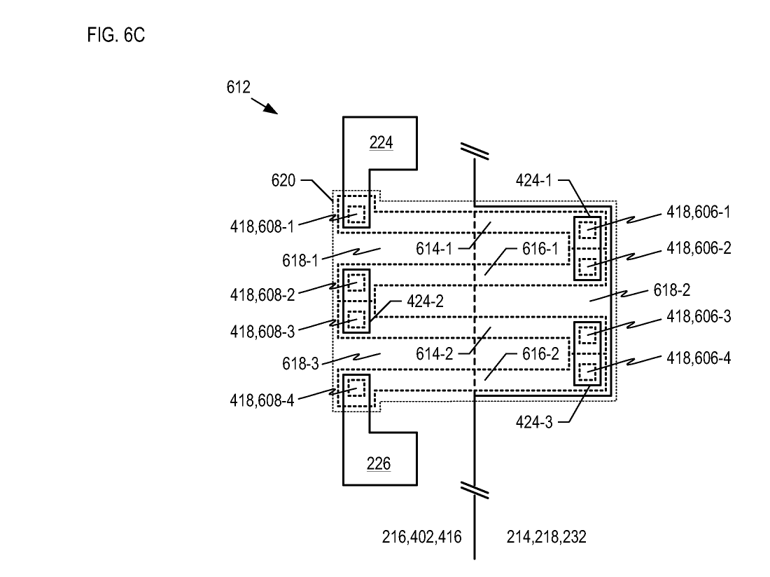

FIG. 6A depicts a top view of details of a temperature sensor in accordance with a first alternative embodiment of the present invention. Temperature sensor 600 comprises silicon strips 602-1, 602-2, and 602-3, traces 604-1, 604-2, and 604-3, and contact pads 224 and 226.

Silicon strips 602-1, 602-2, and 602-3 (collectively referred to as silicon strips 602) are regions of active layer 406, which have been patterned into distinct regions of semiconductor using conventional photolithography and etching techniques. In some embodiments, active layer 406 is a layer of substantially undoped single-crystal silicon. In such embodiments, therefore, silicon strips 602 are undoped single-crystal silicon. Silicon strips 602 collectively define temperature sensor core 412. In some embodiments, silicon strips 602 are doped in similar fashion to regions 408. A portion of each of silicon strips 602 is disposed over cavity 214 and collectively define portion 210 of temperature sensor 600. Each of silicon strips 602 is encapsulated by material of buried dielectric layer 404 and dielectric layer 416, in similar fashion to temperature sensor core 412 described above and with respect to FIGS. 4A-E.

Traces 604-1, 604-2, and 604-3 (collectively referred to as traces 604) are metal lines formed to make electrical contact to silicon strips 602 at vias 418. In some embodiments, traces 604 are polycrystalline semiconductor lines doped with a dopant that is opposite type to that of active layer 406. It should be noted that traces 604 are typically kept thin and narrow to avoid significant bi-material effects in the presence of elevated temperature. Except in the regions of vias 418, traces 604 are electrically isolated from silicon strips 602 by dielectric layer 416.

Hot junctions 606-1, 606-2, and 606-3 (collectively referred to as hot junctions 606) are formed by the metal-semiconductor junctions located at vias 418 within portion 210. In similar fashion cold junctions 608-1, 608-2, and 608-3 (collectively referred to as cold junctions 608) are formed by the metal-semiconductor junctions located at vias 418 outside portion 210 and disposed above bulk layer 216. Hot junctions 606 and cold junctions 608 collectively define a plurality of metal-semiconductor thermocouples that, in turn, collectively define a thermopile (i.e., sensor 600). Sensor 600 develops a voltage between contact pads 224 and 226 based upon the temperature differences between hot junctions 606 and cold junctions 608.

It should be noted that the segmented structure of temperature sensor 600 is substantially enabled by the use of low-stress single-crystal silicon as its core structural material. As discussed above, other commonly used structural materials, such as polysilicon and metals, exhibit high residual stress, stress gradients, self-annealing, and work hardening effects that make them unsuitable and/or unreliable for use as the primary structural material in structures such as that shown in FIG. 6A.

FIG. 6B depicts a top view of details of a temperature sensor in accordance with a second alternative embodiment of the present invention. Temperature sensor 610 comprises temperature sensor core 412, regions 408, traces 604-1, 604-2, and 604-3, and contact pads 224 and 226.

Temperature sensor 610 is analogous to temperature sensor 600; however, temperature sensor 610 is a solid region of active layer 406 that includes regions 408, wherein regions 408 are counter-doped regions. In some embodiments, slots that extend vertically through portion 210 are formed to provide some thermal isolation between individual thermocouples within the thermopile. Such sculpting of temperature sensor 610 is facilitated by the use of low-stress single-crystal silicon as its core structural material.

With respect to segmented temperature sensors, the solid plate-like nature of temperature sensor core 412 affords some or all of the following advantages. Since it is a planar structure, it is less susceptible to bi-material thermal effects. Also, temperature sensor 610 has fewer topographical changes over which traces 604 must be routed. Further, temperature sensor 610 is more mechanically robust and, therefore, suitable for higher flow rate applications. Still further, regions 408 do not need to be doped through the entire thickness of active layer 406.

FIG. 6C depicts a top view of details of a temperature sensor in accordance with a third alternative embodiment of the present invention. Temperature sensor 612 comprises temperature sensor core 412 and contact pads 224 and 226.

Temperature sensor core 612 is a serpentine pattern of semiconductor regions—specifically, p-strips 614-1 and 614-2, and n-strips 616-1 and 616-2.

P-strip 614-1 includes cold junction 608-1 and hot junction 606-1. Cold junction 608-1 is a thermocouple junction formed by the physical contact between p-strip 614-1 and contact 224. Hot junction 608-1 is a thermocouple junction formed by the physical contact between p-strip 614-1 and trace 424-1. In similar fashion, n-strip 616-1 includes cold junction 608-2 and hot junction 606-2. Cold junction 608-2 is a thermocouple junction formed by the physical contact between n-strip 616-1 and trace 424-2. Hot junction 608-1 is a thermocouple junction formed by the physical contact between n-strip 616-1 and trace 424-1. P-strip 614-1 and n-strip 616-1 are in direct physical contact only at their unsupported ends (i.e., the ends over cavity 214). Hot junctions 606-1 and 606-2 are electrically connected in series by trace 424-1.

P-strip 614-2 includes cold junction 608-3 and hot junction 606-3. Cold junction 608-3 is a thermocouple junction formed by the physical contact between p-strip 614-2 and trace 424-2. Hot junction 608-3 is a thermocouple junction formed by the physical contact between p-strip 614-2 and trace 424-3. In similar fashion, n-strip 616-2 includes cold junction 608-4 and hot junction 606-4. Cold junction 608-4 is a thermocouple junction formed by the physical contact between n-strip 616-2 and contact 226. Hot junction 608-4 is a thermocouple junction formed by the physical contact between n-strip 616-2 and trace 424-3. P-strip 614-2 and n-strip 616-2 are in direct physical contact only at their unsupported ends (i.e., the ends over cavity 214). Hot junctions 606-3 and 606-4 are electrically connected in series by trace 424-3. Further, cold junctions 608-2 and 608-3 are electrically connected in series by trace 424-2. As a result, and by virtue of the electrically connectivity afforded by p-strips 614 and n-strips 616, cold junction 608-1, hot junctions 606-1 and 606-2, cold junctions 608-2 and 608-3, hot junctions 606-3 and 606-4, and cold junction 608-4 form a series of Seebeck voltage elements whose voltages add in series.

When temperature sensor 612 is exposed to a thermal gradient between its hot junctions and cold junctions, a voltage differential develops between contacts 224 and 226. This voltage differential is the sum of the Seebeck voltages that develop at each of the cold junctions and hot junctions. These junctions are electrically connected in series by virtue of contact 224, trace 424-1, trace 424-2, trace 424-3, and contact 226, as shown in FIG. 6C.

By virtue of the fact that the unsupported portions of p-strips 614 and n-strips 616 are in physical contact with one another at only their unsupported ends, heat flow between the semiconductor strips is limited and sensitivity of the temperature sensor is improved.

The sculpting of temperature sensor core 620 results in p-strip 614-1 and n-strip 616-1 meeting only at the unsupported end of the first cantilever. Between cold junction 608-1 and hot junction 606-1 (and cold junction 608-2 and hot junction 606-2), p-strip 614-1 and n-strip 616-1 are separated by gap 618-1. In similar fashion, p-strip 614-2 and n-strip 616-2 meet only at the unsupported end of the second cantilever, and are separated by gap 618-3 elsewhere. Also in similar fashion, n-strip 616-1 and p-strip 614-2 are separated by gap 618-2. By virtue of gaps 618-1, 618-2, and 618-3, the thermal isolation of the suspended portion of the thermopile is improved, since heat flow between the p- and n-strips is substantially eliminated.

Once temperature sensor core 620 has been sculpted, dielectric layer 416 is formed to encapsulate the thermopile elements. In some embodiments, gaps 618-1, 618-2, and 618-3 are sufficiently narrow that the formation of dielectric layer 416 acts to substantially fill these gaps with dielectric material (in similar fashion to a “trench refill”).

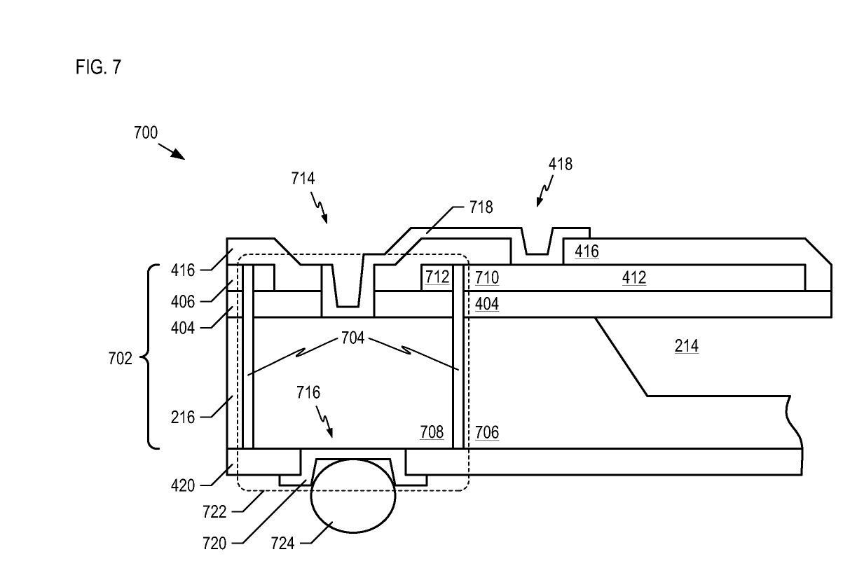

FIG. 7 depicts a cross-sectional diagram of a temperature sensor in accordance with a fourth alternative embodiment of the present invention. Temperature sensor 700 comprises substrate 702, through-substrate contacts 722, interconnects 718, and backside contacts 720. For clarity, only one through-substrate contact, interconnect and backside contact is depicted in FIG. 7.

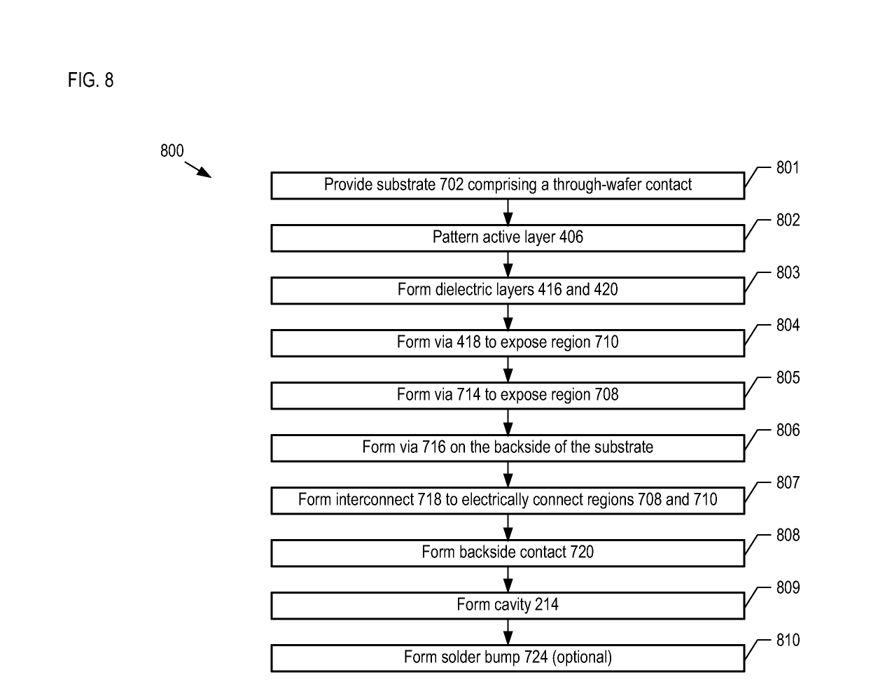

FIG. 8 depicts a method suitable for forming a temperature sensor in accordance with the fourth alternative embodiment of the present invention. Method 800, which comprises operations suitable for forming an element in the active layer of a semiconductor-on-insulator substrate, wherein the element is electrically connected to a backside contact, is described with continuing reference to FIG. 7. Method 800 begins with operation 801, wherein substrate 702 is provided.

Substrate 702 comprises bulk layer 216, buried dielectric 404, and active layer 406. Substrate 702 further comprises isolation region 704, which is an annular region of dielectric material that extends through the thickness of bulk layer 216, thereby enclosing region 708. By virtue of isolation region 704, bulk layer 216 is divided into two electrically isolated, electrically conductive regions, regions 706 and 708. Bulk layer 216 and isolation region 704 collectively define a conventional silicon substrate having a through-wafer contact.

An aspect of the present invention is that conventional through-wafer contact technology can be extended to semiconductor-on-insulator substrates (e.g., SOI wafers) so that devices formed in the active layer can also be electrically accessible to back surface contact pads. To that end, isolation region 704 is extended through the entire thickness of substrate 702—including active layer 406. As a result, and in similar fashion to bulk layer 216, active layer 406 is divided into two electrically isolated, electrically conductive regions, regions 710 and 712.

At operation 802, active layer 406 is patterned to form temperature sensor core 412 within region 710. Operation 802 also removes a portion of region 712 to expose buried dielectric layer 404, thereby forming an area suitable for the subsequent formation of via 714.

At operation 803, dielectric layers 416 and 420 are formed. Dielectric layer 416 encapsulates temperature sensor core 412. Dielectric layer 420 passivates and protects the backside of bulk layer 216 during the formation of cavity 214.

At operation 804, via 418 is formed by etching dielectric layer 416 to expose temperature sensor core 412.

At operation 805, via 714 is fully formed by etching dielectric layer 416 and buried dielectric layer 404 to expose bulk layer 216 within region 708. During operation 805, region 422 is also formed (not shown for clarity).

At operation 806, via 716 is formed by etching dielectric layer 420 to expose the backside of bulk layer 216 within region 708.

At operation 807, interconnect 718 is formed to electrically connect the front side of region 708 and temperature sensor core 412.

At operation 808, backside contact 720 is formed such that it is in electrical contact with the backside of bulk layer 216 within region 708. Backside contact 720, region 708, and interconnect 718 collectively define through-substrate contact 722, which electrically connects backside contact 720 and temperature sensor core 412. Interconnect 718 and contact 720 are analogous to contacts 220, 222, 224, 226, 228, 230, and interconnects 424.

At operation 809, cavity 214 is formed in region 706.

At optional operation 810, solder bump 724 is formed on backside contact 720 to facilitate solder bump bonding of temperature sensor 700 to additional electronics.

By virtue of through-substrate contacts 722, the need for frontside electrical contacts is obviated; therefore, all metal and/or semiconductor surfaces exposed to media flow can be encapsulated by dielectric protective material. As a result, a flow sensor comprising through-substrate contacts can have improved immunity to corrosive media and extended operating life. In addition, metals suitable for use in such flow sensors could include those normally attacked by etch chemicals suitable for forming cavity 214. Further, no wire bonds would be required on the front surface of the flow sensor. Wire bond failures due to stress induced by the flow of media across the flow sensor would, therefore, be eliminated. Finally, backside contacts would facilitate inclusion of interface and signal conditioning electronics formed on the backside of the substrate. Such electronics could be fabricated using conventional IC processing technology and could be easily protected from harsh media during operation. In addition, the inclusion of electronics on the backside of the substrate would not incur a real estate penalty, thereby enabling a potential cost reduction.

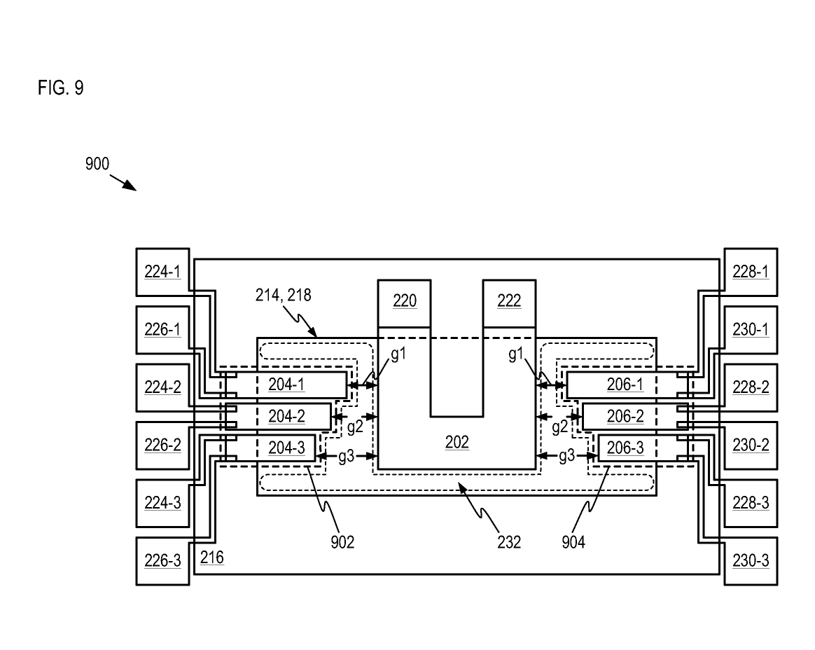

FIG. 9 depicts a top view of details of a flow sensor in accordance with a fifth alternative embodiment of the present invention. Flow sensor 900 comprises heater 202, and temperature sensors 902 and 904.

Temperature sensors 902 and 904 each comprises a plurality of temperature sensing elements, each of which is analogous to temperature sensors 204 and 206, respectively. Each of the temperature sensing elements within its temperature sensor is separated from heater 202 by a different distance. For example, temperature sensor 902 comprises temperature sensor elements 204-1, 204-2, and 204-3, which are separated from heater 202 by gaps g1, g2, and g3, respectively. In similar fashion, temperature sensor 904 comprises temperature sensor elements 206-1, 206-2, and 206-3, which are separated from heater 202 by gaps g1, g2, and g3, respectively.

The temperature sensor elements operate in matched pairs, 204-1 and 206-1, 204-2 and 206-2, and 204-3 and 206-3, to form three substantially independent flow sensors. Each of these flow sensors operates in analogous fashion to flow sensor 200, but is sensitive over a different flow range by virtue of their different separations from heater 202. It would be apparent to one skilled in the art that there is a unique correspondence between the maximum flow rate detectible and the distance between the heater and temperature sensors.

Flow sensor 900 enables an advance over prior-art approaches for sensing flow over a large range of flow rates. Conventional approaches require multiple heaters and multiple temperature sensors that are optimally positioned with respect to their respective heaters. As a result, conventional wide flow range flow sensors require significantly more real estate that flow sensors in accordance with the present invention.

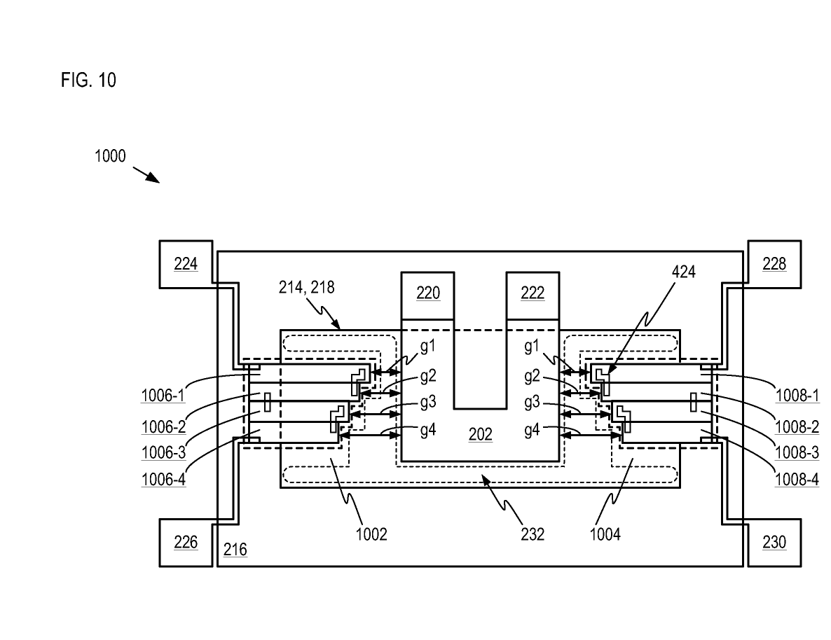

FIG. 10 depicts a top view of details of a flow sensor in accordance with a sixth alternative embodiment of the present invention. Flow sensor 1000 comprises heater 202, and temperature sensors 1002 and 1004.

Temperature sensor 1002 is a thermopile having a plurality of thermocouple elements 1006-1, 1006-2, 1006-3, and 1006-4 (referred to collectively as thermocouples 1006), which are electrically connected in series via interconnects 424.

Temperature sensor 1004 is a thermopile having a plurality of thermocouple elements 1008-1, 1008-2, 1008-3, and 1008-4 (referred to collectively as thermocouples 1008), which are electrically connected in series via interconnects 424.

Temperature sensors 1002 and 1004 are analogous to temperature sensors 204 and 206, with the exception that the individual thermocouples that compose their thermopiles are at a variety of distances away from heater 202. As a result, each thermopile is capable of measuring an expanded range of flow rates.

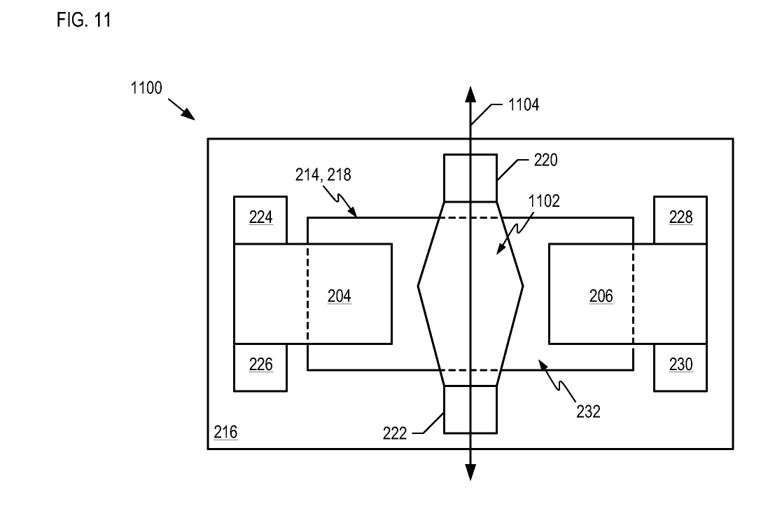

FIG. 11 depicts a top view of details of a flow sensor in accordance with a seventh alternative embodiment of the present invention. Flow sensor 1100 comprises heater 1102, and temperature sensors 204 and 206.

Heater 1102 is a heater having a shaped profile so that it is characterized by a resistance profile along axis 1104. By virtue of its non-uniform resistance profile, heater 1102 provides a more uniform temperature along its length.

A prior art heater element that has a uniform cross-section along its length inherently loses more heat to the substrate near its anchor points (i.e., points at which the heater element is joined to the substrate) due to the close proximity of thermally conductive substrate material. As a result, these heater elements require more power to produce the same amount of heat as heater 1102. Further, flow sensors based upon such prior-art heater elements typically exhibit reduced sensitivity due to fact that fluid that flows along a channel cross-section is not heated uniformly across the length of the heater element.

It should be noted that flow sensors 900, 1100, and 1000 are enabled by the use of low-stress single-crystal semiconductor as the core structural material for the elements disposed over cavity 214. The use of such material enables the sculpting of these elements without incurring significant deformation due to residual stress and stress gradients in the material. In some embodiments, the operational temperature range of the flow sensors is extended by the fact that the dielectric layers below and above the core material of the flow sensor have substantially the same thickness. As a result, bi-material effects, such as those exhibited by prior art devices, is mitigated or eliminated.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. A method for forming a flow sensor, wherein the method comprises:
forming a cavity in a first region of a bulk layer;
forming a heater element having a first portion disposed above the first region, wherein the heater element comprises an inner core of substantially single-crystal material and an outer shell comprising a first dielectric; and
forming a first temperature sensor having a second portion disposed above the first region, wherein the first temperature sensor comprises an inner core of substantially single-crystal material and an outer shell comprising the first dielectric;
wherein the first portion and the second portion are physically decoupled from one another in the first region.

2. The method of claim 1 wherein the heater element and first temperature sensor are formed by operations comprising:
etching an active layer, wherein the active layer is disposed on a buried dielectric layer that is disposed on the bulk layer, wherein the buried dielectric layer comprises the first dielectric; and
depositing a first layer of the first dielectric, wherein the first layer of first dielectric and the buried dielectric have substantially the same thickness.

3. The method of claim 2 further comprising physically decoupling the first portion and second portion in the first region by removing the buried dielectric layer in a first area of the first region.

4. The method of claim 2 wherein the layer of first dielectric is deposited with a thickness substantially equal to the thickness of the buried dielectric layer.

5. The method of claim 1 wherein the heater element and first temperature sensor are formed by operations comprising:
etching an active layer, wherein the active layer is disposed on a buried dielectric layer that is disposed on the bulk layer; and
forming a layer of the first dielectric by oxidizing exposed surfaces of the first structure.

6. The method of claim 1 wherein the first temperature sensor is formed by forming a p-n junction in the second portion.

7. The method of claim 1 wherein the first temperature sensor is formed by forming a metal-semiconductor junction in the second portion.

8. The method of claim 1 further comprising:
providing an active layer disposed on a buried dielectric layer that is disposed on the bulk layer, wherein the active layer comprises single-crystal silicon;
forming the inner core of the heater element from a first region of the active layer; and
forming the inner core of the temperature sensor from a second region of the active layer.

9. The method of claim 1 further comprising:
providing an active layer disposed on a buried dielectric layer that is disposed on the bulk layer, wherein the active layer comprises silicon-carbide;
forming the inner core of the heater element from a first region of the active layer; and
forming the inner core of the temperature sensor from a second region of the active layer.

10. The method of claim 1 further comprising:
providing a substrate comprising the active layer disposed on the buried dielectric layer disposed on the bulk layer, wherein the substrate has a first surface that is proximate to the active layer and a second surface that is distal to the active layer, and wherein the active layer comprises the first surface;
forming a first isolation region through the thickness of the substrate to define a first electrically conductive region in the bulk layer and a second electrically conductive region in the bulk layer, wherein the first electrically conductive region and the second electrically conductive region are electrically isolated from one another by the first isolation region, and wherein the first electrically conductive region comprises a portion of the second surface; and
electrically connecting the first electrically conductive region and one of the first portion and second portion.

11. The method of claim 10 wherein electrically connecting the first electrically conductive region and the one of the first portion and second portion includes operations comprising:
forming the first isolation region such that it further defines a third electrically conductive region in the active layer and a fourth electrically conductive region in the active layer, wherein the third electrically conductive region and fourth electrically conductive region are electrically isolated from one another by the first isolation region, and wherein the fourth electrically conductive region and the one of the first portion and second portion are electrically connected;
forming a via through the third electrically conductive region to expose the buried dielectric layer in a second area;
removing the buried dielectric layer in the second area to expose the first electrically conductive region; and
forming an electrically conductive trace, wherein the trace and the fourth electrically conductive region are electrically connected, and further wherein the trace and the first electrically conductive region are electrically connected.

12. The method of claim 1 further comprising forming a second temperature sensor having a third portion disposed above the first region, wherein the second temperature sensor comprises an inner core of substantially single-crystal material and an outer shell comprising the first dielectric, and wherein the first portion interposes the second portion and the third portion.

13. The method of claim 1 further comprising forming a second temperature sensor having a third portion disposed above the first region, wherein the second temperature sensor comprises an inner core of substantially single-crystal material and an outer shell comprising the first dielectric, and wherein the second portion and the third portion are on the same side of the first portion, and wherein the first portion and the second portion are separated by a first separation, and further wherein the first portion and the third portion are separated by a second separation.

14. A flow sensor comprising:
a heater element having a first portion, wherein the heater element comprises an inner core of substantially single-crystal material and an outer shell comprising a first dielectric;
a first temperature sensor having a second portion, wherein the first temperature sensor comprises an inner core of substantially single-crystal material and an outer shell comprising the first dielectric;
wherein the first portion and second portion are disposed above a cavity formed in a first region of a bulk layer, and wherein the first portion and the second portion are physically decoupled from one another in the first region.

15. The flow sensor of claim 14 wherein the first temperature sensor comprises a p-n junction.

16. The flow sensor of claim 14 wherein the first temperature sensor comprises a metal-semiconductor junction.

17. The flow sensor of claim 14 further comprising a second temperature sensor having a third portion, wherein the second temperature sensor comprises an inner core of substantially single-crystal material and an outer shell comprising the first dielectric, and wherein the third portion is disposed above the cavity, and further wherein the first portion, second portion, and third portion are physically decoupled from one another in the first region.

18. The flow sensor of claim 17 wherein the first portion interposes the second portion and the third portion.

19. The flow sensor of claim 14 further comprising:
a substrate comprising the bulk layer, a buried dielectric layer, and an active layer that comprises single-crystal material, wherein the substrate comprises a first surface that is a surface of the active layer, and wherein the substrate comprises a second surface that is distal to the active layer; and
a through-substrate contact comprising a portion of the second surface;
wherein the portion of the second surface and one of the first portion and the second portion are electrically connected.

20. The flow sensor of claim 14 wherein the single-crystal material is single-crystal silicon.

21. The flow sensor of claim 14 wherein the single-crystal material is single-crystal silicon-carbide.

22. A flow sensor comprising:
a substrate comprising an active layer disposed on a buried dielectric layer disposed on a bulk layer, wherein the active layer comprises a single-crystal material, and wherein the buried dielectric layer comprises silicon dioxide;
a heater element comprising a first portion of the active layer, a first portion of the buried dielectric layer, and a first layer of a first dielectric, wherein the first layer is disposed on the first portion of the active layer; and
a first temperature sensor comprising a second portion of the active layer, a second portion of the buried dielectric layer, and second layer of the first dielectric, wherein the second layer is disposed on the second portion of the active layer;
wherein the bulk layer comprises first region comprising a cavity, and wherein the first portion of the buried dielectric layer and the second portion of the dielectric layer are disposed over the cavity, and wherein the first portion of the buried dielectric layer and the second portion of the dielectric layer are physically decoupled from one another in the first region.

23. The flow sensor of claim 22 wherein the active layer comprises single-crystal silicon.

24. The flow sensor of claim 22 wherein the active layer comprises single-crystal silicon-carbide.

25. The flow sensor of claim 22 wherein each of the active layer and the bulk layer comprises single-crystal silicon.

26. The flow sensor of claim 22 further comprising a second temperature sensor comprising a third portion of the active layer, a third portion of the buried dielectric layer, and a third layer of the first dielectric, wherein the third layer is disposed on the third portion of the active layer.

27. The flow sensor of claim 26 wherein the first portion interposes the second portion and the third portion.

28. The flow sensor of claim 26, wherein the second portion and the third portion are on the same side of the first portion, and wherein the first portion and the second portion are separated by a first separation, and further wherein the first portion and the third portion are separated by a second separation.

29. The flow sensor of claim 22 wherein the heater element has an axis, and wherein the heater element is characterized by a resistance that is a function of position along the axis.

30. The flow sensor of claim 22 wherein the first layer has a first thickness, and wherein the buried dielectric layer has a second thickness, and further wherein the first thickness and the second thickness are substantially equal.
